(19) United States
(12) Patent Application Publication
(10) Pub. No.: US 2012/0193781 A1
(43) Pub. Date: Aug. 2, 2012

(54) CUSTOMIZED RF MEMS CAPACITOR ARRAY USING REDISTRIBUTION LAYER

(75) Inventors: Julio Costa, Oak Ridge, NC (US); Jonathan Hale Hammond, Oak Ridge, NC (US); Thomas Scott Morris, Lewisville, NC (US)

(73) Assignee: RF MICRO DEVICES, INC., Greensboro, NC (US)

(21) Appl. No.: 13/311,687

(22) Filed: Dec. 6, 2011

Related U.S. Application Data
(60) Provisional application No. 61/436,832, filed on Jan. 27, 2011.

(51) Int. Cl. H01L 23/48; H01L 23/498; H01L 21/768

(52) U.S. Cl. 257/737; 438/637; 438/613; 257/773; 257/E21.575; 257/E23.011; 257/E23.068

(57) ABSTRACT

Disclosed is a method for fabricating a customized micro-electromechanical systems (MEMS) integrated circuit using at least one redistribution layer. The method includes steps of providing a substrate on which MEMS components are fabricated and coupling predetermined ones of the MEMS components via the redistribution traces.

### RELATED APPLICATIONS

This application claims the benefit of provisional patent application Ser. No. 61/436,832, filed Jan. 27, 2011, the disclosure of which is hereby incorporated herein by reference in its entirety.

### FIELD OF THE DISCLOSURE

The present disclosure relates to a method of fabricating integrated circuit packaging having a redistribution layer (RDL) and in particular to a micro-electromechanical systems (MEMS) integrated circuit having at least one RDL.

### BACKGROUND

MEMS manufacturing companies specializing in MEMS technology do not necessarily produce MEMS integrated circuits that can be directly integrated into an RF module such as a front end module for a mobile terminal such as a cellular handset. In particular, RF performance of a standard MEMS device array chip may not be configured to fulfill requirements of specific RF applications and products needed in the mobile terminal. Moreover, companies developing MEMS integrated circuits frequently lack RF expertise and are hesitant to enable a foundry model of business that would allow end users to produce custom RF components using their technology. Thus, a need exists for a method to customize MEMS integrated circuits after manufacture by the MEMS manufacturing company in order to provide the MEMS integrated circuits with the specific and customized RF performance required for RF applications.

### SUMMARY

One embodiment of the present disclosure relates a method for fabricating a customized micro-electromechanical systems (MEMS) integrated circuit through the use of at least one redistribution layer (RDL). The method includes steps of providing a substrate on which MEMS components are fabricated and coupling predetermined ones of the MEMS components via redistribution traces that are conductors making up an RDL. The method produces a customized MEMS integrated circuit with enhanced electrical attributes that provide improved RF performance. In at least one embodiment, the method provides one or more RDLs that include MEMS components and electrical components formed from redistribution traces.

Those skilled in the art will appreciate the scope of the present invention and realize additional aspects thereof after reading the following detailed description in association with the accompanying drawings.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 shows a schematic of a related art tuning circuit known as a pi-network, which can be configured using the embodiments of the present disclosure.

FIGS. 2A-2D depict initial and middle steps of a process flow in accordance with the present disclosure for adding a redistribution layer (RDL) to a micro-electromechanical systems (MEMS) process layer.

FIGS. 3A-3B depict finishing steps of the process flow shown initiated in FIG. 2A.

FIG. 4 is a schematic view of an exemplary customized MEMS integrated circuit resulting from a process flow such as the one shown in FIGS. 2A-2D and 3A-3B.

FIG. 5 is a schematic view of the customized MEMS integrated circuit further including a plurality of redistribution layers used to realize custom circuits as well as fabricate new MEMS devices and/or electrical components according to the present disclosure.

FIG. 6 is a cross sectional view of a customized MEMS integrated circuit having a planar surface formed by a repassivation layer added in accordance with the present disclosure.

FIG. 7 is a block diagram of a mobile terminal that incorporates an embodiment of the customized MEMS integrated circuit of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

The embodiments disclosed herein provide simple and low cost means for customizing MEMS integrated circuits such as standard MEMS device array chips for use in specific RF applications. In accordance with embodiments of the present disclosure, at least one redistribution layer (RDL) is employed to configure standard MEMS device array chip into a customized MEMS integrated circuit that provides improved RF performance necessary for RF applications developed by an end user company. In this way, the end user company can purchase standard MEMS device array chips from a MEMS company and craft them into RF MEMS integrated circuits by grouping and connecting MEMS components such as capacitors in an RF-suitable fashion by employing embodiments of the present disclosure. Thus, the embodiments of the present disclosure enable both small companies that produce standard MEMS device array chips and large integrators to operate in a common business area without conflicts of interest.

The present embodiments also enable the MEMS companies to focus on their expertise of making better MEMS components while allowing RF companies to focus on improving their RF applications by converting the standard MEMS device array chips produced by the MEMS companies into MEMS integrated circuits having high RF performance. For the purpose of this disclosure, MEMS components include those actuated thermally, electrostatically, magnetically, piezoelectrically and fluidically.

An RDL process is a commonly available re-configuration process used by the RF industry. However, the RDL process presently used by the RF industry is traditionally used to adapt an existing wirebond design chip so that it can be used in flip-chip form. Another traditional use of the RDL process is for increasing or decreasing pad pitch to be compatible with subsequent three dimensional assembly requirements. The present disclosure provides embodiments that adapts the traditional RDL process to enable re-configuration of standard MEMS device array chips using post-MEMS processing that incorporates RDLs. In particular, the RDLs described in the present disclosure are novel and are usable to customize the RF performance of a MEMS integrated circuit in the form of a standard MEMS device array chip by making connections between the MEMS devices fixed in standard positions.

MEMS integrated circuits such as standard MEMS device array chips typically include MEMS components in standardized positions. The MEMS components comprising MEMS integrated circuits include, but are not limited to, voltage variable capacitors, capacitive switches, voltage actuated metal contact switches, high Q inductors, and transmission lines. Non-MEMS components comprising MEMS integrated circuits include, but are not limited to, MIM (metal-insulator-metal) capacitors formed using the low resistance thick metallization layer commonly available in RF MEMS technologies, integrated inductors and resistors.

Applications where such customization may be desirable include filter tuning, power amplifier (PA) impedance matching, PA tuning, antenna impedance matching, and antenna tuning. These impedance matching or tuning circuits are typically made up of tunable elements like capacitors and inductors.

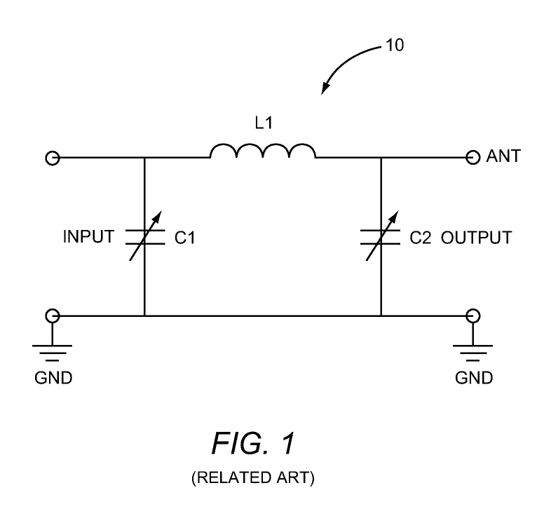

FIG. 1 shows the schematic of a related art tuning circuit 10 known as a pi-network. As used herein, the terms “coupled to” and/or “coupling” mean direct electrical coupling. A first capacitor C1 and a second capacitor C2 are voltage variable capacitors that are realizable using MEMS technology. An inductor L1 in the pi-network can either be a MEMS inductor integrated with the first capacitor C1 and the second capacitor C2 or the inductor can be fabricated as a custom component. Similar customizations can be implemented to form other circuitry that provides enhanced RF performance. The pi-network of FIG. 1 is usable for PA and antenna (ANT) matching and/or tuning. Various other circuitries are realizable via embodiments of the present disclosure.

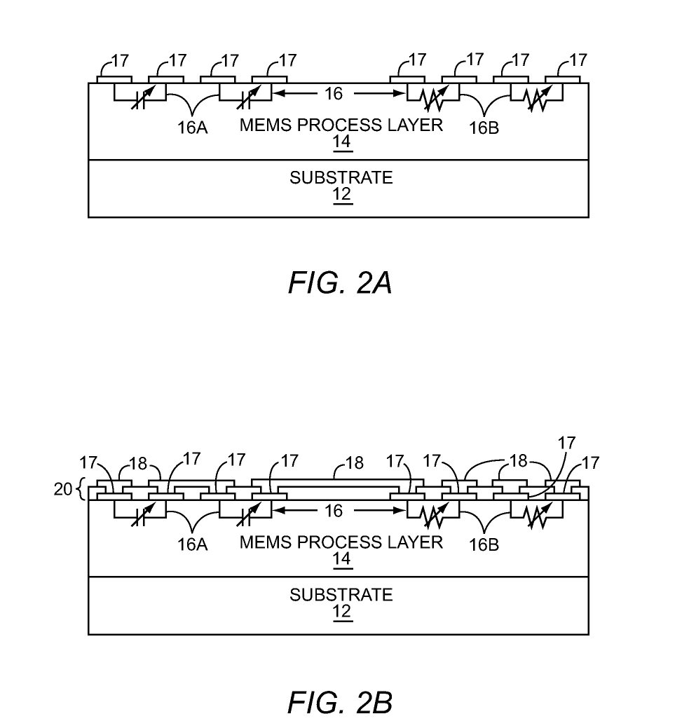

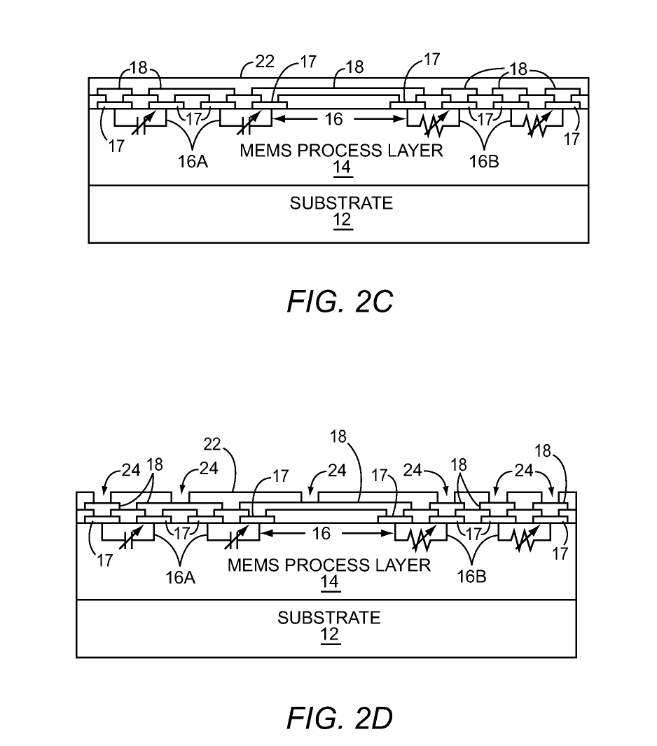

FIGS. 2A-2D and FIGS. 3A-3B depict a process flow in accordance with the present disclosure. The process begins by providing a substrate 12 on which a MEMS process layer 14 is fabricated (FIG. 2A). The MEMS process layer 14 includes MEMS components 16 such as MEMS variable capacitors 16A and MEMS metal contact switches 16B. The MEMS components 16 include conductive pads 17. The process flow continues by coupling predetermined ones of the MEMS components 16 via redistribution traces 18 that make up an RDL 20 (FIG. 2B). An insulation layer 22 is added over the redistribution traces 18 (FIG. 2C). The insulation layer 22 can be a passivation layer. The process flow continues by etching openings through the insulation layer 22 to expose predetermined connector locations 24 on top of the redistribution traces 18 (FIG. 2D).

FIGS. 3A-3B depict finishing steps of the process flow shown initiated in FIGS. 2A-2D. The process flow resumes by coupling connectors 26 to the redistribution traces 18 at the predetermined connector locations 24 (FIG. 3A). A laminate 28 having conductive traces 30 with conductive pads 32 is coupled to the coupling connectors 26 (FIG. 3B).

Generally, the process depicted in FIGS. 2A-2D and FIGS. 3A-3B configures the RDL 20 to customize standard MEMS device array chips by setting capacitance values and/or resistance values. Customization of standard MEMS device array chips are also realized by using the RDL 20 to make series, parallel, and shunt connections between components comprising standard MEMS device array chips. Moreover, customization of circuit performance is achieved by placing higher power/higher performance branches of components in locations that yield better thermal conduction, power transfer, and/or lower parasitic losses.

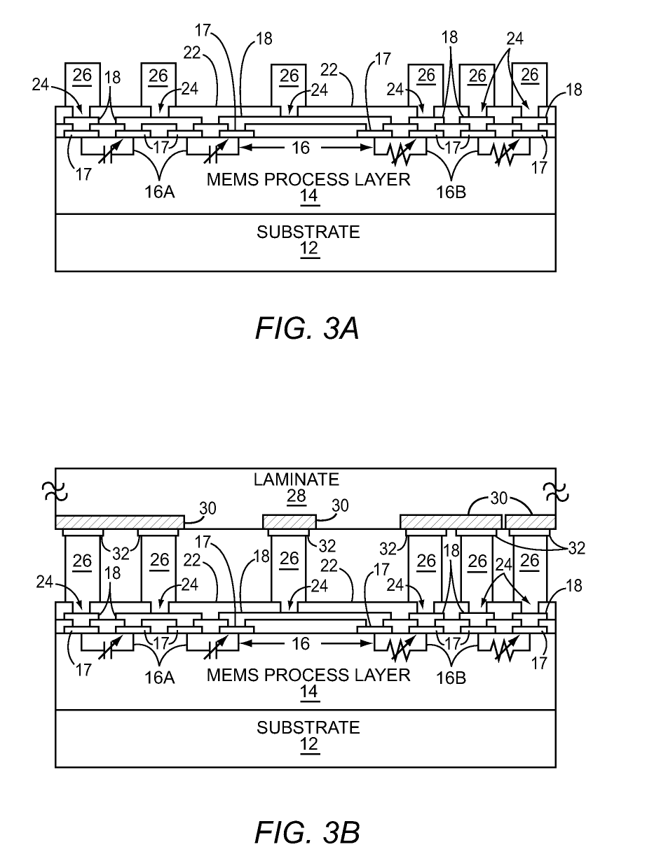

FIG. 4 is a schematic top view of an exemplary customized MEMS integrated circuit 34 that results from a process flow such as shown in FIGS. 2A-2D and FIGS. 3A-3B. In particular, FIG. 4 depicts how the RDL 20 having redistribution traces 18 is used to combine MEMS components of a standard MEMS array chip to realize various circuit topologies including RF specific circuit topologies. Exemplary circuit topologies include coupling MEMS components 16 in series 36 and parallel 38, and coupling MEMS components 16 with a common ground (GND) to realize a shunt connection 40. It is to be understood that more complex circuit topologies are realizable using embodiments of the present disclosure and that the simple exemplary topologies depicted in FIG. 4 do not limit the scope of the disclosure. Moreover, the RDL 20 is usable to form additional components 42, which can be MEMS components or passive electrical components such as inductors, capacitors, and resistors. The RDL 20 can also be used traditionally to redistribute ground and power connections, as well as adjust position or pitch of the coupling connectors 26 (FIG. 3B) in relation to the laminate 28 (FIG. 3B). The customized MEMS integrated circuit 34 also typically includes circuitry 44 that includes a supply, device control logic, and at least one charge pump.

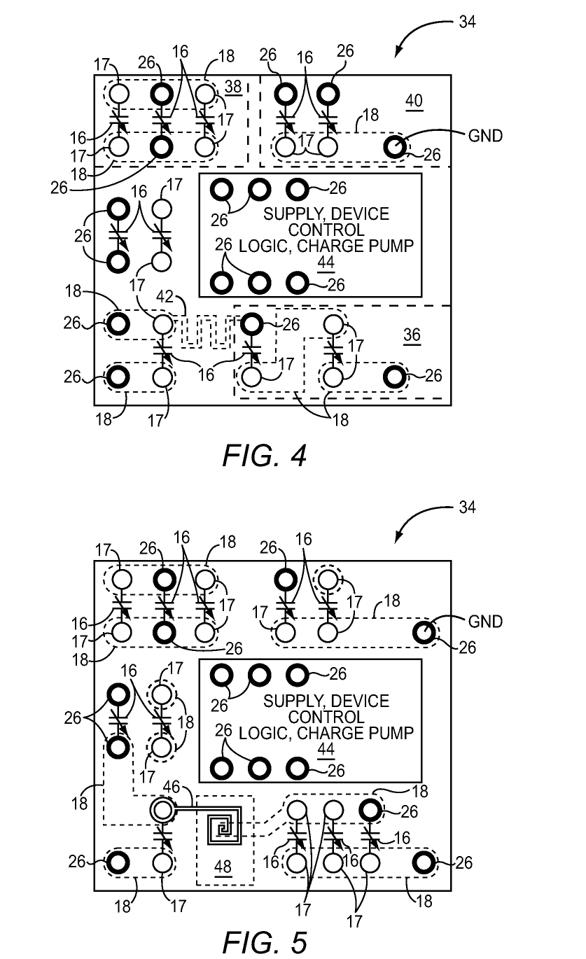

FIG. 5 is a schematic view of the customized MEMS integrated circuit further including a plurality of redistribution layers used to realize custom circuits as well as fabricate new MEMS devices and/or electrical components according to the present disclosure. In particular, a second RDL 46 is used to further connect devices in a useful way. In this case, it is shown that the two RDL layers could be used to fabricate a spiral inductor 48. The spiral inductor 48 is formed in the second RDL 46 and connected to adjacent capacitors by the first RDL 20. The two layers could also be used as needed to achieve additional series and parallel combinations like those depicted in FIG. 4.

A MEMS die supplier can provide a standard MEMS array chip and it can then be customized to an integrator company's specifications or preferences using one or more RDLs. As a result, no new masks, or lots are required from the MEMS die supplier or foundry.

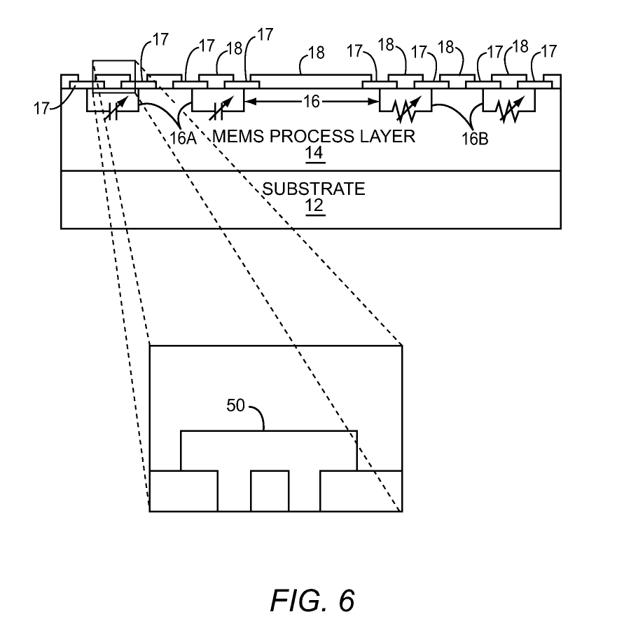

The RDL 20 also has a benefit when arranged as in FIG. 6. A repassivation layer 50 in the RDL 20 is usable to planarize a non-planar surface of a MEMS wafer to enable manufacturable metal layer process by ensuring no issues with step coverage. Typically steps are formed during the process flow shown in FIGS. 2A and 2B due to thick low loss metal layers and thin film packaging dielectric layers (not shown).

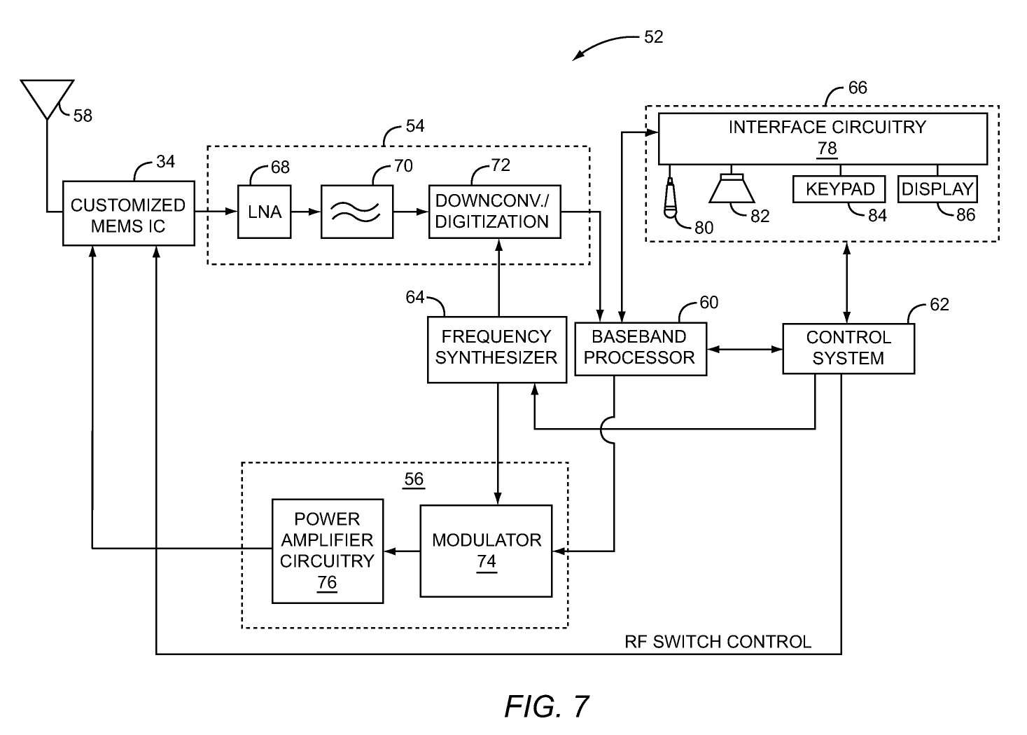

Turning now to FIG. 7, the customized MEMS integrated circuit 34 is incorporated in a mobile terminal 52, such as a cellular handset, a personal digital assistant (PDA), or the like. The basic architecture of the mobile terminal 52 may include a receiver front end 54, an RF transmitter section 56, an antenna 58, a baseband processor 60, a control system 62, a frequency synthesizer 64, and an interface 66. The receiver front end 54 receives information bearing RF signals from one or more remote transmitters provided by a base station. A low noise amplifier (LNA) 68 amplifies the signal. A filter circuit 70 minimizes broadband interference in the received signal, while downconversion and digitization circuitry 72 downconverts the filtered, received signal to an intermediate or baseband frequency signal, which is then digitized into one or more digital streams. The receiver front end 54 typically uses one or more mixing frequencies generated by the frequency synthesizer 64.

The baseband processor 60 processes the digitized received signal to extract the information or data bits conveyed in the received signal. This processing typically comprises demodulation, decoding, and error correction operations. As such, the baseband processor 60 is generally implemented in one or more digital signal processors (DSPs).

On the transmit side, the baseband processor 60 receives digitized data, which may represent voice, data, or control information from the control system 62 which it encodes for transmission. The encoded data is output to the RF transmitter section 56, where it is used by a modulator 74 to modulate a carrier signal that is at a desired transmit frequency. Power amplifier (PA) circuitry 76 amplifies the modulated carrier signal to a level appropriate for transmission from the antenna 58.

A user may interact with the mobile terminal 52 via the interface 66, which may include interface circuitry 78 associated with a microphone 80, a speaker 82, a keypad 84, and a display 86. The interface circuitry 78 typically includes analog-to-digital converters, digital-to-analog converters, amplifiers, and the like. Additionally, it may include a voice encoder/decoder, in which case it may communicate directly with the baseband processor 60.

The microphone 80 will typically convert audio input, such as the user's voice, into an electrical signal, which is then digitized and passed directly or indirectly to the baseband processor 60. Audio information encoded in the received signal is recovered by the baseband processor 60 and converted into an analog signal suitable for driving the speaker 82 by the interface circuitry 78. The keypad 84 and the display 86 enable the user to interact with the mobile terminal 52 by inputting numbers to be dialed, address book information, or the like, as well as monitoring call progress information.

Those skilled in the art will recognize improvements and modifications to the preferred embodiments of the present disclosure. All such improvements and modifications are considered within the scope of the concepts disclosed herein and the claims that follow.

What is claimed is:

1. A method for fabricating a customized micro-electromechanical systems (MEMS) integrated circuit using at least one redistribution layer, comprising:
providing a substrate on which MEMS components are fabricated; and
coupling predetermined ones of the MEMS components via redistribution traces.

2. The method of claim 1 further including providing an insulation layer over the redistribution traces.

3. The method of claim 2 wherein the insulation layer is a passivation layer.

4. The method of claim 2 further including etching openings through the insulation layer to expose predetermined connector locations on top of the redistribution traces.

5. The method of claim 4 further including coupling connectors to the redistribution traces at the predetermined connector locations.

6. The method of claim 5 wherein the connectors are solder bumps.

7. The method of claim 5 wherein the connectors are copper pillars.

8. The method of claim 4 wherein the predetermined connector locations align with conductive pads on a provided laminate to be coupled to the MEMS integrated circuit.

9. The method of claim 1 wherein coupling predetermined ones of the MEMS components via redistribution traces results in a series coupling of the predetermined ones of the MEMS components.

10. The method of claim 1 wherein coupling predetermined ones of the MEMS components via redistribution traces results in a parallel coupling of the predetermined ones of the MEMS components.

11. The method of claim 1 wherein coupling predetermined ones of the MEMS components via redistribution traces results in combinations of series couplings and parallel couplings of the predetermined ones of the MEMS components.

12. The method of claim 1 wherein the MEMS components are MEMS variable capacitors.

13. The method of claim 1 wherein the MEMS components are MEMS metal contact switches.

14. The method of claim 1 wherein select ones of the redistribution traces are fabricated into MEMS components.

15. The method of claim 1 wherein select ones of the redistribution traces are fabricated into inductors.

16. The method of claim 1 wherein select ones of the redistribution traces are fabricated into capacitors.

17. The method of claim 1 wherein select ones of the redistribution traces are fabricated into resistors.

18. The method of claim 1 wherein select ones of the redistribution traces are fabricated into transformers.

19. The method of claim 1 wherein at least one other redistribution layer is usable to couple predetermined ones of the MEMS components.

20. A MEMS integrated circuit having a redistribution layer comprising:
a substrate including MEMS components; and
redistribution traces coupling predetermined ones of the MEMS components.

21. The MEMS integrated circuit of claim 20 further including an insulation layer over the redistribution traces.

22. The MEMS integrated circuit of claim 21 wherein the insulation layer is a passivation layer.

23. The MEMS integrated circuit of claim 21 further including openings through the insulation layer that expose predetermined connector locations on top of the redistribution traces.

24. The MEMS integrated circuit of claim 23 further including connectors coupled to the redistribution traces at the predetermined connector locations.

25. The MEMS integrated circuit of claim 24 wherein the connectors are solder bumps.

26. The MEMS integrated circuit of claim 24 wherein the connectors are conductive pillars.

27. The MEMS integrated circuit of claim 23 wherein the predetermined connector locations align with conductive pads on a provided laminate to be coupled to the MEMS integrated circuit.

28. The MEMS integrated circuit of claim 20 wherein predetermined ones of the MEMS components are coupled in series via the redistribution traces.

29. The MEMS integrated circuit of claim 20 wherein predetermined ones of the MEMS components are coupled in parallel via the redistribution traces.

30. The MEMS integrated circuit of claim 20 wherein predetermined ones of the MEMS components are coupled in series and parallel combinations via the redistribution traces.

31. The MEMS integrated circuit of claim 20 wherein the MEMS components are MEMS variable capacitors.

32. The MEMS integrated circuit of claim 20 wherein the MEMS components are MEMS metal contact switches.

33. The MEMS integrated circuit of claim 20 wherein select ones of the redistribution traces are fabricated into MEMS components.

34. The MEMS integrated circuit of claim 20 wherein select ones of the redistribution traces are fabricated into inductors.

35. The MEMS integrated circuit claim 20 wherein select ones of the redistribution traces are fabricated into capacitors.

36. The MEMS integrated circuit of claim 20 wherein select ones of the redistribution traces are fabricated into resistors.

37. The MEMS integrated circuit of claim 20 wherein select ones of the redistribution traces are fabricated into transformers.

38. The MEMS integrated circuit claim 20 further including at least one other redistribution layer that is usable to couple predetermined ones of the MEMS components.
